(19) United States
(12) Patent Application Publication
(10) Pub. No.: US 2025/0027990 A1
(43) Pub. Date: Jan. 23, 2025

(54) CHARGED-PARTICLE BEAM APPARATUS FOR VOLTAGE-CONTRAST INSPECTION AND METHODS THEREOF

(71) Applicant: ASML Netherlands B.V., Veldhoven (NL)

(72) Inventors: Datong ZHANG, San Jose, CA (US); Xiaoyu JI, San Jose, CA (US); Weiming REN, San Jose, CA (US); Xuedong LIU, San Jose, CA (US); Chia Wen LIN, Saratoga, CA (US)

(73) Assignee: ASML Netherlands B.V., Veldhoven (NL)

(21) Appl. No.: 18/713,108

(22) PCT Filed: Oct. 26, 2022
(86) PCT No.: PCT/EP2022/079908

§ 371 Date: May 23, 2024

Related U.S. Application Data
(60) Provisional application No. 63/283,199, filed on Nov. 24, 2021.

(51) Int. Cl. G01R 31/307; H01J 37/28

(52) U.S. Cl. CPC G01R 31/307; H01J 37/28

(57) ABSTRACT

Systems and methods of inspecting a sample using a charged-particle beam apparatus with enhanced probe current and high current density of the primary charged-particle beam are disclosed. The apparatus includes a charged-particle source, a first condenser lens configured to condense the primary charged-particle beam and operable in a first mode and a second mode, wherein: in the first mode, the first condenser lens is configured to condense the primary charged-particle beam, and in the second mode, the first condenser lens is configured to condense the primary charged-particle beam sufficiently to form a crossover along the primary optical axis. The apparatus further includes a second condenser lens configured to adjust a first beam current of the primary charged-particle beam in the first mode and adjust a second beam current of the primary charged-particle beam in the second mode, the second beam current being larger than the first beam current.

### CROSS-REFERENCE TO RELATED APPLICATIONS

This application claims priority of U.S. application 63/283,199 which was filed on 24 Nov. 2021 and which is incorporated herein in its entirety by reference.

### TECHNICAL FIELD

The embodiments provided herein disclose a single charged-particle beam apparatus, and more particularly an inspection apparatus with enhanced beam probe current using a crossover mode for voltage-contrast inspection of defects.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy and yield in defect detection become more important. Although multiple electron beams may be used to increase the throughput, either the probe current for each beamlet may be insufficient for voltage-contrast inspection in VNAND or 3D-NAND structures, or the increased Coulomb interaction may negatively impact the image quality, rendering the inspection apparatus inefficient and inadequate for their desired purpose. In some cases, a high intensity electron emission source may be used to generate large current beams for probing, however, such sources may be extremely unstable, expensive, or inefficient.

### SUMMARY

One aspect of the present disclosure is directed to a charged particle beam apparatus to inspect a sample. The apparatus may include a charged-particle source configured to emit charged particles, an aperture plate to form a primary charged-particle beam along a primary optical axis from the emitted charged particles, a condenser lens configuration configured to condense the primary charged-particle beam based on a selected mode of operation of the apparatus, wherein the selected mode of operation comprises a first mode and a second mode, and wherein—in the first mode of operation, the condenser lens configuration may be configured to condense the primary charged-particle beam, and in the second mode of operation, the condenser lens configuration may be configured to condense the primary charged-particle beam sufficiently to form a crossover on a crossover plane between the condenser lens configuration and an objective lens of the apparatus.

Another aspect of the disclosure is directed to a charged particle beam apparatus to inspect a sample. The apparatus may include a charged-particle source, a first condenser lens configured to condense the primary charged-particle beam and operable in a first mode and a second mode, wherein: in the first mode, the first condenser lens is configured to condense the primary charged-particle beam, and in the second mode, the first condenser lens is configured to condense the primary charged-particle beam sufficiently to form a crossover along the primary optical axis. The apparatus may further include a second condenser lens configured to adjust a first beam current of the primary charged-particle beam in the first mode and adjust a second beam current of the primary charged-particle beam in the second mode, the second beam current being larger than the first beam current.

Another aspect of the disclosure is directed to a method of inspecting a sample using a charged-particle beam apparatus. The method may comprise forming a primary charged-particle beam along a primary optical axis from charged particles emitted by a charged-particle source; condensing, using a condenser lens configuration, the primary charged-particle beam based on a selected mode of operation of the apparatus comprising a first mode and a second mode, wherein: operating in the first mode comprises condensing the primary charged-particle beam using the condenser lens configuration, and operating in the second mode comprises condensing the primary charged-particle beam sufficiently to form a crossover between the condenser lens configuration and an objective lens of the apparatus; and focusing, using an objective lens, the primary charged-particle beam exiting the condenser lens configuration on a surface of the sample to form a probe spot.

Another aspect of the disclosure is directed to a method of inspecting a sample using a charged-particle beam apparatus. The method may comprise forming a primary charged-particle beam along a primary optical axis from charged particles emitted by a charged-particle source; condensing the primary charged-particle beam, using a first condenser lens operable in a first mode and a second mode, wherein in the first mode, the first condenser lens is configured to condense the primary charged-particle beam, and in the second mode, the first condenser lens is configured to condense the primary charged-particle beam to form a crossover along the primary optical axis; and adjusting, using a second condenser lens, a first beam current of the primary charged-particle beam in the first mode and a second beam current of the primary charged-particle beam in the second mode, wherein the second beam current is larger than the first beam current.

Yet another aspect of the present disclosure is directed to a non-transitory computer readable medium storing a set of instructions that is executable by one or more processors of a charged-particle beam apparatus to cause the charged particle beam apparatus to perform a method. The method may comprise forming a primary charged-particle beam along a primary optical axis from charged particles emitted by a charged-particle source; condensing, using a condenser lens configuration, the primary charged-particle beam based on a selected mode of operation of the apparatus comprising a first mode and a second mode, wherein: operating in the first mode comprises condensing the primary charged-particle beam using the condenser lens configuration, and operating in the second mode comprises condensing the primary charged-particle beam sufficiently to form a crossover between the condenser lens configuration and an objective lens of the apparatus; and focusing, using an objective lens, the primary charged-particle beam exiting the condenser lens configuration on a surface of the sample to form a probe spot.

Yet another aspect of the present disclosure is directed to a non-transitory computer readable medium storing a set of instructions that is executable by one or more processors of a charged-particle beam apparatus to cause the charged particle beam apparatus to perform a method. The method may comprise forming a primary charged-particle beam along a primary optical axis from charged particles emitted by a charged-particle source; condensing the primary charged-particle beam, using a first condenser lens operable in a first mode and a second mode, wherein in the first mode, the first condenser lens is configured to condense the primary charged-particle beam, and in the second mode, the first condenser lens is configured to condense the primary charged-particle beam sufficiently to form a crossover along the primary optical axis; and adjusting, using a second condenser lens, a first beam current of the primary charged-particle beam in the first mode and a second beam current of the primary charged-particle beam in the second mode, wherein the second beam current is larger than the first beam current.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 is a schematic diagram illustrating an exemplary electron beam inspection (EBI) system, consistent with embodiments of the present disclosure.

FIG. 2 is a schematic diagram illustrating an exemplary electron beam tool that can be a part of the exemplary electron beam inspection system of FIG. 1, consistent with embodiments of the present disclosure.

FIGS. 3A, 3B, and 3C illustrate schematic diagrams of an exemplary electron beam inspection tool operating in a normal mode or in a crossover mode, respectively, consistent with embodiments of the present disclosure.

FIG. 4 illustrates a data graph for a software assisted mode-switching capability of an exemplary electron beam inspection tool, consistent with embodiments of the present disclosure.

FIG. 5 illustrates a simulated data plot of a relationship between resolution and probe current of an electron beam for a plurality of aperture sizes in a normal mode and a crossover mode, consistent with embodiments of the present disclosure.

FIG. 6 illustrates a simulated plot of a relationship between resolution and probe current of an electron beam in a normal mode and a crossover mode, consistent with embodiments of the present disclosure.

FIG. 7 is a process flowchart representing an exemplary method 700 of inspecting a sample using a beam crossover mode in an electron beam inspection apparatus, consistent with embodiments of the present disclosure.

FIG. 8 is a process flowchart representing an exemplary method 800 of inspecting a sample using a beam crossover mode in an electron beam inspection apparatus, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC, thereby rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

Detecting buried defects in vertical high-density structures, such as 3D NAND flash memory devices, can be challenging. One of several ways to detect buried or on-surface electrical defects in such devices is by using a voltage contrast method in a SEM. In this method, electrical conductivity differences in materials, structures, or regions of a sample cause contrast differences in SEM images thereof. In the context of defect detection, an electrical defect under the sample surface may generate a charging variation on the sample surface, so the electrical defect can be detected by a contrast in the SEM image of the sample surface. To enhance the voltage contrast, a process called pre-charging or flooding may be employed in which the region of interest of the sample may be exposed to a high current beam before an inspection using a low current but high imaging resolution beam. For the inspection, some of the advantages of flooding may include uniform charging of the wafer to minimize distortion of images due to charging effects, and in some cases, increase of charging of the wafer to enhance difference of defective and surrounding non-defective features in images, among other things.

Though the voltage-contrast (VC) technique is useful in detecting buried or on-surface electrical defects in complex device structures, the technique may suffer from some drawbacks. Defect inspection using voltage-contrast techniques includes a two-step process. The first step includes pre-charging a surface of a sample by flooding the surface with charged-particles (e.g., electrons) to highlight the electrical defects, and the second step includes inspecting the flooded surface to detect the highlighted defects. To enhance the voltage contrast, the pre-charging step may be performed by exposing the sample surface to a high current beam. In the inspection step following the pre-charging step, the sample may be inspected using a low current beam for high resolution imaging. For defect detection by VC in a SEM, switching between the pre-charging and the inspection modes may include adjusting the beam current, for example, by selecting the aperture size of a Coulomb Aperture Array (CAA). Selecting and aligning apertures to produce the desired beam current may take several seconds and may reduce the overall inspection throughput, among other things. Further, in some cases, such as defect inspection for 3D-NAND devices, the maximum achievable beam current at which imaging resolution is still acceptable may be insufficient to detect buried electrical defects, rendering the existing VC technique either inadequate or inefficient, or both. Therefore, for voltage contrast defect detection, it may be desirable to enhance the probe current of the probing beam, while maintaining good imaging resolution, such that the sample may be pre-charged and inspected using the same high current beam, eliminating the need to switch between flooding and inspection modes.

In currently existing SEMs, some of the ways to obtain higher probe beam current include increasing the intensity of the electron source emission or increasing the diameter of the beam-limiting aperture to allow more electrons to pass through. However, these techniques may introduce electron source instability and image quality deterioration, both of which may negatively impact the throughput of the process or the quality of the inspection results. For example, increasing the intensity of the electron source emission may cause instability of the source, affecting the performance and reliability of the inspection tool. Increasing the diameter of the beam-limiting aperture may increase the aberrations such as spherical aberration, chromatic aberration, or other high-order off-axis aberrations, of image-forming elements (e.g., objective lens, or deflectors). The increased aberrations may cause deterioration in image resolution, thereby impacting the defect detection capabilities of the inspection apparatus. Therefore, it may be desirable to increase the beam current using a technique that improves the defect detection efficiency, while maintaining the high throughput and image resolution.

As previously described, voltage-contrast imaging (VCI) includes a two-step process. For defect detection by VCI in a SEM, switching between the pre-charging and the inspection steps may include adjusting the beam current, for example, by selecting the aperture size of a Coulomb Aperture Array (CAA). Selecting and aligning apertures to produce the desired beam current may take several seconds and may reduce the overall inspection throughput, among other things. Further, in some cases, such as defect inspection for 3D-NAND devices, the maximum achievable beam current may be insufficient to detect buried electrical defects, rendering the existing VCI technique either inadequate or inefficient, or both. Therefore, for voltage contrast defect detection, it may be desirable to enhance the probe current of the probing beam such that the sample may be pre-charged and inspected using the same high current beam, eliminating the need to switch between flooding and inspection modes.

Further, in complex devices structures, such as 3D-NAND devices including multiple layers of different materials and geometries, the rate of charge dissipation or rate of charge decay may be different. This difference in charge dissipation may negatively impact the charge uniformity after the pre-charging or the flooding step of the two-step process. For example, some layers may discharge at a higher rate than the others, causing a charge non-uniformity in the region of interest. Furthermore, this disparity in the charge uniformity may be aggravated based on the timing difference between the flooding and the inspection step. In some cases, charge losses occurring in the time period required to switch between the flooding and inspection step may lead to a reduction in voltage-contrast signal intensity or a complete loss of signal. Therefore, it may be desirable to perform voltage-contrast inspection with higher probe currents in a single step to minimize charge non-uniformity and charge losses, thus improving inspection throughput and imaging resolution.

In some embodiments of the present disclosure, a single-beam apparatus for inspecting a sample is disclosed. The apparatus may include a condenser lens configured to focus a primary charged-particle beam generated by a charged-particle source based on a selected mode of operation. In a non-crossover mode, the condenser lens may focus and collimate the primary charged-particle beam, and in a crossover mode, the condenser lens is configured to form a beam crossover between the condenser lens and the objective lens. The apparatus may further include a controller having circuitry and configured to switch an operation of the apparatus between the non-crossover mode and the crossover mode by adjusting the electrical excitation of the condenser lens such that the beam crossover is formed.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

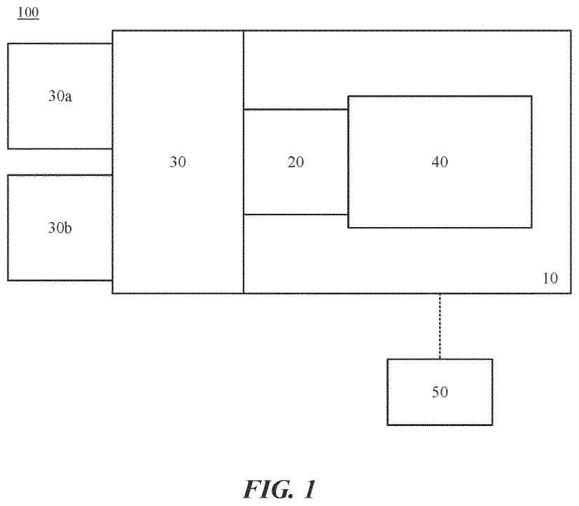

Reference is now made to FIG. 1, which illustrates an exemplary electron beam inspection (EBI) system 100 consistent with embodiments of the present disclosure. As shown in FIG. 1, charged particle beam inspection system 100 includes a main chamber 10, a load-lock chamber 20, an electron beam tool 40, and an equipment front end module (EFEM) 30. Electron beam tool 40 is located within main chamber 10. While the description and drawings are directed to an electron beam, it is appreciated that the embodiments are not used to limit the present disclosure to specific charged particles and charged-particle beam apparatuses. For example, a charged-particle may refer to an electron, an ion, or any positively or negatively charged particle and a charged-particle beam apparatus may refer to an electron beam apparatus, or an ion beam apparatus, or any apparatus using electrons and ions such as a SEM, or a focused ion beam (FIB) in combination with SEM.

EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 30 transport the wafers to load-lock chamber 20.

Load-lock chamber 20 is connected to a load/lock vacuum pump system (not shown), which removes gas molecules in load-lock chamber 20 to reach a first pressure below the atmospheric pressure. After reaching the first pressure, one or more robot arms (not shown) transport the wafer from load-lock chamber 20 to main chamber 10. Main chamber 10 is connected to a main chamber vacuum pump system (not shown), which removes gas molecules in main chamber 10 to reach a second pressure below the first pressure. After reaching the second pressure, the wafer is subject to inspection by electron beam tool 40. In some embodiments, electron beam tool 40 may comprise a single-beam inspection tool. In other embodiments, electron beam tool 40 may comprise a multi-beam inspection tool.

Controller 50 may be electronically connected to electron beam tool 40 and may be electronically connected to other components as well. Controller 50 may be a computer configured to execute various controls of charged particle beam inspection system 100. Controller 50 may also include processing circuitry configured to execute various signal and image processing functions. While controller 50 is shown in FIG. 1 as being outside of the structure that includes main chamber 10, load-lock chamber 20, and EFEM 30, it is appreciated that controller 50 can be part of the structure.

While the present disclosure provides examples of main chamber 10 housing an electron beam inspection system, it should be noted that aspects of the disclosure in their broadest sense, are not limited to a chamber housing an electron beam inspection system. Rather, it is appreciated that the foregoing principles may be applied to other chambers as well.

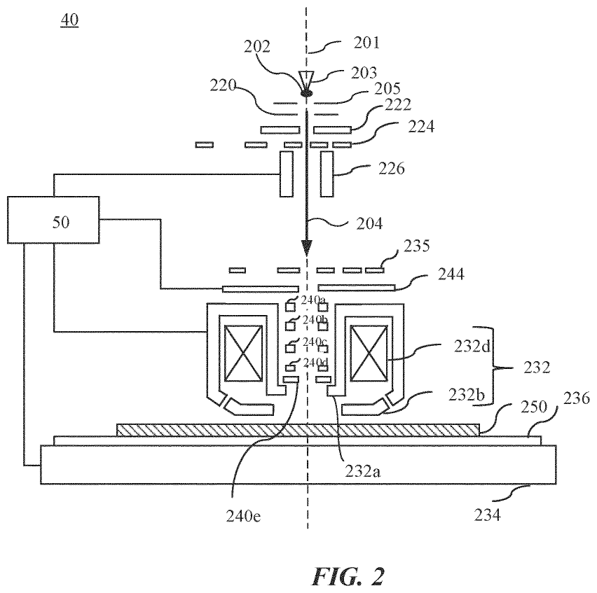

Reference is now made to FIG. 2, which illustrates a schematic diagram illustrating an exemplary configuration of electron beam tool 40 that can be a part of the exemplary charged particle beam inspection system 100 of FIG. 1, consistent with embodiments of the present disclosure. Electron beam tool 40 (also referred to herein as apparatus 40) may comprise an electron emitter, which may comprise a cathode 203, an extractor electrode 205, a gun aperture 220, and an anode 222. Electron beam tool 40 may further include a Coulomb aperture array 224, a condenser lens 226, a beam-limiting aperture array 235, an objective lens assembly 232, and an electron detector 244. Electron beam tool 40 may further include a sample holder 236 supported by motorized stage 234 to hold a sample 250 to be inspected. It is to be appreciated that other relevant components may be added or omitted, as needed.

In some embodiments, electron emitter may include cathode 203, an anode 222, wherein primary electrons can be emitted from the cathode and extracted or accelerated to form a primary electron beam 204 that forms a primary beam crossover 202. Primary electron beam 204 can be visualized as being emitted from primary beam crossover 202.

In some embodiments, the electron emitter, condenser lens 226, objective lens assembly 232, beam-limiting aperture array 235, and electron detector 244 may be aligned with a primary optical axis 201 of apparatus 40. In some embodiments, electron detector 244 may be placed off primary optical axis 201, along a secondary optical axis (not shown).

Objective lens assembly 232, in some embodiments, may comprise a modified swing objective retarding immersion lens (SORIL), which includes a pole piece 232a, a control electrode 232b, a beam manipulator assembly comprising deflectors 240a, 240b, 240d, and 240e, and an exciting coil 232d. In a general imaging process, primary electron beam 204 emanating from the tip of cathode 203 is accelerated by an accelerating voltage applied to anode 222. A portion of primary electron beam 204 passes through gun aperture 220, and an aperture of Coulomb aperture array 224, and is focused by condenser lens 226 so as to fully or partially pass through an aperture of beam-limiting aperture array 235. The electrons passing through the aperture of beam-limiting aperture array 235 may be focused to form a probe spot on the surface of sample 250 by the modified SORIL lens and deflected to scan the surface of sample 250 by one or more deflectors of the beam manipulator assembly. Secondary electrons emanated from the sample surface may be collected by electron detector 244 to form an image of the scanned area of interest.

In objective lens assembly 232, exciting coil 232d and pole piece 232a may generate a magnetic field. A part of sample 250 being scanned by primary electron beam 204 can be immersed in the magnetic field and can be electrically charged, which, in turn, creates an electric field. The electric field may reduce the energy of impinging primary electron beam 204 near and on the surface of sample 250. Control electrode 232b, being electrically isolated from pole piece 232a, may control, for example, an electric field above and on sample 250 to reduce aberrations of objective lens assembly 232 and control focusing situation of signal electron beams for high detection efficiency, or avoid arcing to protect sample. One or more deflectors of beam manipulator assembly may deflect primary electron beam 204 to facilitate beam scanning on sample 250. For example, in a scanning process, deflectors 240a, 240b, 240d, and 240e can be controlled to deflect primary electron beam 204, onto different locations of top surface of sample 250 at different time points, to provide data for image reconstruction for different parts of sample 250. It is noted that the order of 240a-e may be different in different embodiments.

Backscattered electrons (BSEs) and secondary electrons (SEs) can be emitted from the part of sample 250 upon receiving primary electron beam 204. A beam separator (not shown) can direct the secondary or scattered electron beam(s), comprising backscattered and secondary electrons, to a sensor surface of electron detector 244. The detected secondary electron beams can form corresponding beam spots on the sensor surface of electron detector 244. Electron detector 244 can generate signals (e.g., voltages, currents) that represent the intensities of the received secondary electron beam spots, and provide the signals to a processing system, such as controller 50. The intensity of secondary or backscattered electron beams, and the resultant secondary electron beam spots, can vary according to the external or internal structure of sample 250. Moreover, as discussed above, primary electron beam 204 can be deflected onto different locations of the top surface of sample 250 to generate secondary or scattered electron beams (and the resultant beam spots) of different intensities. Therefore, by mapping the intensities of the secondary electron beam spots with the locations of sample 250, the processing system can reconstruct an image that reflects the internal or external structures of wafer sample 250.

In some embodiments, controller 50 may comprise an image processing system that includes an image acquirer (not shown) and a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detector 244 of apparatus 40 through a medium such as an electrical conductor, optical fiber cable, portable storage media, IR, Bluetooth, internet, wireless network, wireless radio, among others, or a combination thereof. In some embodiments, the image acquirer may receive a signal from electron detector 244 and may construct an image. The image acquirer may thus acquire images of regions of sample 250. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, controller 50 may include measurement circuitries (e.g., analog-to-digital converters) to obtain a distribution of the detected secondary electrons and backscattered electrons. The electron distribution data collected during a detection time window, in combination with corresponding scan path data of a primary beam 204 incident on the sample (e.g., a wafer) surface, can be used to reconstruct images of the wafer structures under inspection. The reconstructed images can be used to reveal various features of the internal or external structures of sample 250, and thereby can be used to reveal any defects that may exist in the wafer.

In some embodiments, controller 50 may control motorized stage 234 to move sample 250 during inspection. In some embodiments, controller 50 may enable motorized stage 234 to move sample 250 in a direction continuously at a constant speed. In other embodiments, controller 50 may enable motorized stage 234 to change the speed of the movement of sample 250 over time depending on the steps of scanning process.

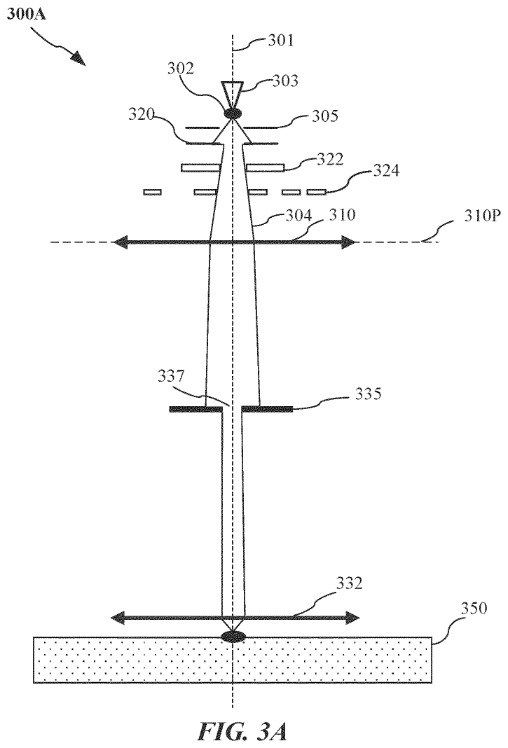

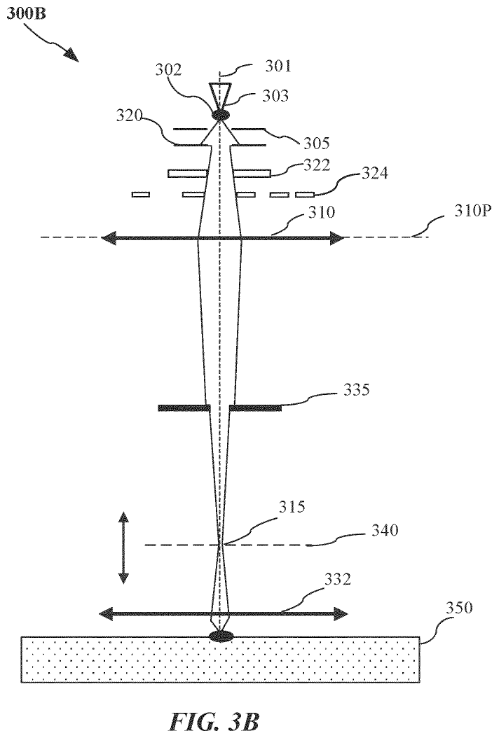

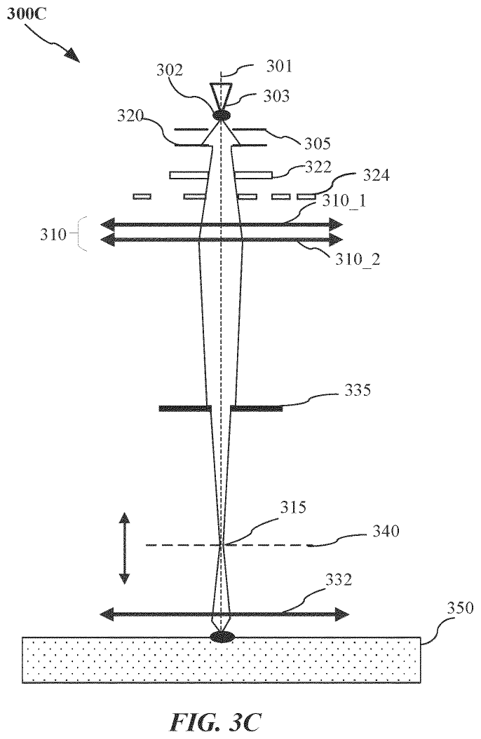

Reference is now made to FIGS. 3A-3C, which are schematic diagrams of exemplary configurations of a charged-particle beam inspection tool, consistent with embodiments of the present disclosure. In the configuration shown in FIG. 3A, single-beam inspection apparatus 300A, also referred to herein as electron-optics system 300A or apparatus 300A may comprise an electron emitter, which may comprise a cathode 303, an extractor electrode 305, a gun aperture 320, and an anode 322. In some embodiments, primary electrons may be emitted from cathode 303 and extracted or accelerated to form a primary electron beam 304 along a primary optical axis 301. Primary electron beam 304 can be visualized as being emitted from primary beam crossover 302. It is appreciated that cathode 303, extractor electrode 305, gun aperture plate 320, and anode 322 may be substantially similar to the corresponding elements described in FIG. 2 and may perform substantially similar functions. Apparatus 300A may further include an objective lens 332. Although not illustrated, apparatuses 300A, 300B, and 300C of FIGS. 3A, 3B, and 3C, respectively, may further include a primary projection optical system, a secondary imaging system, and an electron detection device, among other components as appropriately needed.

In some embodiments, electron source or the electron emitter may be configured to emit primary electrons (exemplary charged-particles) from the cathode and extracted or accelerated to form primary electron beam 304 (exemplary charged-particle beam) that forms a primary beam crossover (virtual or real) 302. In some embodiments, primary electron beam 304 can be visualized as being emitted from primary beam crossover 302 along a primary optical axis 301. In some embodiments, one or more elements of apparatus 300 may be aligned with primary optical axis 301.

FIG. 3A illustrates a schematic of an exemplary configuration of apparatus 300A operating in a normal mode, also referred to herein as a non-crossover mode. In the non-crossover mode of operation, condenser lens 310 may be configured to receive and focus primary electron beam 304. Condenser lens 310 may be disposed on a principal plane 310P substantially perpendicular to primary optical axis 301. As used herein, “substantially perpendicular” refers to the degree of orthogonality between planes, axes, or between a plane and an axis. For example, the angle subtended by a principal plane of a condenser lens substantially perpendicular to a primary optical axis may be 90°±0.01°, or the standard deviation may be even smaller such that the angle is essentially 90°. As used herein, “substantially parallel” indicates that the planes are extended in the same direction such that the planes would never intersect with each other and are essentially parallel.

In some embodiments, condenser lens 310 may be positioned downstream from the electron source. As used in the context of this disclosure, “downstream” refers to a position of an element along the path of primary electron beam 304 starting from electron source or cathode 303, and “immediately downstream” refers to a position of a second element along the path of primary electron beam 304 such that there are no other elements between the first and the second element. For example, as illustrated in FIG. 3A, condenser lens 310 may be positioned immediately downstream from anode 322 of the electron source such that there are no other optical or electro-optical elements placed between anode 322 and condenser lens 310. Such a configuration may be useful, among other things, in reducing the height of the electro-optical column of apparatus 300A and in reducing the structural complexity thereof.

In some embodiments, an aperture plate (e.g., a gun aperture plate 320) may be placed between cathode 303 and condenser lens 310 to block off peripheral electrons of primary electron beam 304 before being incident on condenser lens 310, to reduce Coulomb interaction effects, among other things. In some embodiments, a pre-beam limit aperture array, also referred to herein as a Coulomb aperture array 324 may be placed between anode 322 and condenser lens 310. Coulomb aperture array 324 may be substantially similar to and may perform substantially similar functions as Coulomb aperture array 224 of FIG. 2.

Coulomb aperture array 324 may comprise multiple apertures configured to allow a portion of primary electron beam 304 while blocking peripheral electrons. In some embodiments, gun aperture plate 320 may be used to block peripheral electrons at an early stage before being incident on anode 322 and coulomb aperture array 324 may be used to block peripheral electrons of primary electron beam 304 exiting anode 322 but before being incident on condenser lens 324. In this way, the Coulomb interaction effect above beam-limit aperture array 335 may be reduced to a great degree.

In some embodiments, Coulomb aperture array 324 may be implemented as a conducting plate including apertures or holes of similar or dissimilar sizes. In some embodiments, apertures of coulomb aperture array 324 may be uniformly or non-uniformly spaced apart. In some embodiments, a position of Coulomb aperture array 324 may be adjustable along a X-axis and a Y-axis in a plane orthogonal to primary optical axis 301 such that an aperture of a desired size may be selected for primary electron beam 304 to pass through.

In the normal mode of operation, as illustrated in FIG. 3A, condenser lens 310 may be configured to condense primary electron beam 304 such that after exiting condenser lens 310, primary electron beam 304 is incident substantially perpendicular on beam-limit aperture array 335 and may pass through an aperture 337.

In some embodiments, beam-limit aperture array 335 may include a plurality of apertures spaced apart to allow a portion of primary electron beam 304 to pass through while blocking the peripheral electrons. In some embodiments, beam-limit aperture array 335 may be implemented via a conducting planar structure such as, but not limited to, a metal plate with through holes.

In some embodiments, the beam current of primary electron beam 304 may be determined based on the size of the aperture of beam-limit aperture array 335 through which primary electron beam 304 may pass. In some embodiments, beam-limit aperture array 335 may comprise a plurality of beam-limit apertures having uniform sizes, shapes, cross-sections, or pitch. In some embodiments, the sizes, shapes, cross-sections, pitches, etc. may be non-uniform as well. The beam-limit apertures may be configured to limit the current of the beam by, for example, limiting the number of electrons passing through the aperture based on the size or shape of the apertures.

In some embodiments, beam-limit aperture array 335 may be movable along an X-axis and a Y-axis in a plane orthogonal to primary optical axis 301 such that primary electron beam 304 may be incident upon an aperture of a desired shape and size. For example, beam-limit aperture array 335 may comprise a plurality of rows of apertures having a shape and a size, wherein apertures within each row have similar sizes and shapes. The position of beam-limit aperture array 335 along the X-Y axes may be adjusted so one of the apertures having the desired sizes and shapes may be exposed to primary electron beam 304.

In some embodiments, beam-limit aperture array 335 may be disposed downstream from condenser lens 310 such that the condensed primary electron beam 304 exiting condenser lens 310 is directly and perpendicularly incident on beam-limit aperture array 335.

Although the size of aperture 337 of beam-limit aperture array 335 may ultimately determine the probe current of primary electron beam 304 incident on sample 350, in some embodiments, it may also depend on the size of the aperture of coulomb aperture array 324. For example, in some cases, where a maximum probe current may be desirable, a combination of the largest aperture of coulomb aperture array 324 and the largest aperture of beam-limit aperture array may be aligned with primary optical axis to allow the maximum number of electrons passing through the column.

Objective lens 332 may be configured to receive and focus the primary electron beam 304 exiting beam-limit aperture array 335 on a surface of a sample 350 to form a probe spot. It is to be appreciated that objective lens 332 may be substantially similar to and may perform substantially similar functions as objective lens 232 of FIG. 2. Other configurations of objective lens 332 may also be used, as appropriate.

In the normal mode of operation, although the probe current of primary electron beam 304 may be increased by selecting a larger beam limit aperture, doing so may generate off-axis aberrations such as chromatic and spherical aberrations, which could negatively impact the resolution and throughput. Further, for VC inspection and imaging in a single step, the probe current requirements may be higher than the maximum achievable probe current through a higher intensity electron source, or a larger aperture, or a combination of both. Furthermore, because the maximum achievable current, while maintaining the resolution, may be limited, in some cases multiple imaging scans may be required to get the desirable voltage contrast. On the other hand, a large probe current may allow a user to get the desirable voltage contrast in fewer imaging scans, preferably a single scan, resultantly improving the inspection throughput.

A large probe current of the primary electron beam may be desirable in detection of electrical defects using voltage contrast techniques in complex three-dimensional structures such as VNAND or 3D-NAND devices, among other things. In addition to improving electrical defect detection efficiency, large probe current may also be desirable in improving the yield of backscattered electrons (BSE) for physical defect detection techniques. One of several ways to achieve large probe beam current may include operating the inspection system in a crossover mode.

In a crossover mode of operation, as illustrated in apparatus 300B of FIG. 3B, an electron source or cathode 303 may generate primary electron beam 304 traveling along primary optical axis 301.

Condenser lens 310 may receive primary electron beam 304 and condense the electrons of primary electron beam 304 sufficiently such that the beam forms a crossover at a crossover point 315 on a crossover plane 340 substantially perpendicular to primary optical axis 301.

In some embodiments, beam crossover may be formed between condenser lens 310 and objective lens 332. In some embodiments, beam crossover may be formed between beam-limit aperture array 335 and objective lens 332, as shown in FIG. 3B. The location of beam crossover 315 may be adjusted along primary optical axis 301 based on an electrical excitation of condenser lens 310. The location of beam crossover 315 may substantially coincide with primary optical axis 304.

In some embodiments, condenser lens 310 may comprise an electromagnetic lens placed downstream from the electron source and configured to condense primary electron beam 304 based on the focusing power of the electromagnetic lens. The focusing power of condenser lens 310 may be adjusted based on the electrical excitation of the electromagnetic lens. Focusing power, as used herein, refers to the degree to which the lens converges or diverges the incident charged-particle (e.g., an electron). In the case of an electromagnetic lens, the electrical excitation of condenser lens 310 may be adjusted by applying or adjusting an applied electrical signal, typically a current signal, received from a controller (e.g., controller 50 of FIG. 2). Adjusting the condenser lens current may adjust the focusing power of condenser lens 310, which may change the convergence angle of primary electron beam 304, thereby adjusting the location of beam crossover 315 along primary optical axis 301. As an example, increasing the focusing power of condenser lens 310 by adjusting the applied electrical excitation signal may cause primary electron beam 304 to converge at a higher angle and to form beam crossover 315 closer to beam-limit aperture array 335 along primary optical axis 301 with respect to objective lens 332. In contrast, decreasing the focusing power of condenser lens 310 by adjusting the electrical excitation signal may cause primary electron beam 304 to converge at a smaller angle and to form beam crossover 315 farther from beam-limit aperture array 335 and closer to objective lens 332, along primary optical axis 301. Convergence angle, as used herein, refers to the angle formed by primary electron beam 304 with respect to primary optical axis 301, after exiting condenser lens 310.

In some embodiments, condenser lens 310 may comprise an electrostatic lens configured to condense primary electron beam 304 based on the focusing power of the electrostatic lens. The focusing power of condenser lens 310 may be adjusted based on the electrical excitation of the electrostatic lens. Adjusting the electrical excitation of an electrostatic lens may include adjusting an applied electrical signal, typically a voltage signal, received from controller 50.

Referring to FIG. 3C, condenser lens 310 of apparatus 300C may comprise two electromagnetic lenses 310_1 and 310_2. In some embodiments, condenser lens 310 of apparatus 300C may comprise a first lens implemented by a compound electromagnetic lens, electrostatic lens, or an electromagnetic lens, and a second lens implemented by a compound electromagnetic lens, electrostatic lens, or an electromagnetic lens. It is to be appreciated that, although not illustrated, any suitable permutation and combination of lenses may be implemented, as appropriate.

Generally, a magnetic lens may generate less aberration than an electrostatic lens but may occupy more space than an electrostatic lens. Therefore, a compound electromagnetic lens may be employed in systems with physical space limitations and stricter aberration tolerances. A compound electromagnetic lens may include an electrostatic lens and a magnetic lens. The magnetic lens of the compound lens may include a permanent magnet. The magnetic lens of the compound lens may provide a portion of the total focusing power of the compound lens, while the electrostatic lens may make up the remaining portion of the total focusing power.

In some embodiments, electromagnetic lens 310_1 may be configured to perform a coarse adjustment of beam current of primary electron beam 304. Electromagnetic lens 310_1 may include an electrically conducting coil configured to generate a magnetic field upon electric current being passed through and the magnitude of magnetic field generated per unit of current passing through may be determined based on the characteristics of the coil such as, but not limited to, number of windings, material of the coil, core material, among other factors. For example, if electromagnetic lens 310_1 is configured for coarse adjustment of beam current, a small adjustment of the electrical excitation (e.g., a current signal) may cause a large increase or decrease in the magnetic field, thereby causing primary electron beam 304 to form a crossover between condenser lens 310 and objective lens 332.

Electromagnetic lens 310_2 of condenser lens 310 may be configured to perform a fine adjustment of beam current of primary electron beam 304. In some embodiments, as an example, electromagnetic lens 310_2 may be used to adjust the location of beam crossover 315 along primary optical axis 301. For example, if electromagnetic lens 310_2 is configured for fine adjustment of beam current, an adjustment of the electrical excitation (e.g., a current signal) may cause a change in the focusing power or convergence angle, thereby causing primary electron beam 304 to form a crossover closer to or farther away from objective lens 322, along primary optical axis 301. The probe current of primary electron beam 304 may thus be adjusted based on the electrical excitation of condenser lens 310. In some embodiments, although not illustrated, it is to be appreciated that condenser lens 310 may comprise two sets of coils wound around a magnetic core material. A first set of coils may be configured to enable coarse adjustment of beam current and a second set of coils may be configured to perform fine adjustment of beam current.

In some embodiments, the electrical excitation signal, for example, a current signal, may be applied to electromagnetic lenses 310_1 and 310_2 through controller 50. In some embodiments, controller 50 may be configured to independently control and adjust the current signal applied to electromagnetic lenses 310_1 and 310_2.

In some embodiments, electromagnetic lens 310_1 may be positioned downstream from the electron source (e.g., cathode 303) and electromagnetic lens 310_2 may be positioned immediately downstream from electromagnetic lens 310_1 such that electromagnetic lens 310_1 and electromagnetic lens 310_2 may be located upstream from beam-limit aperture array 335.

In some embodiments, although not shown, condenser lens 310_1 and 310_2 of condenser lens 310 of apparatus 300C may be coplanar. In the coplanar configuration, condenser lens 3101 may comprise a first set of coils and condenser lens 3102 may comprise a second set of coils, each of the first and the second set of coils wound around a core material. In some embodiments, condenser lens 310_1, in a first setting, may be configured to focus primary electron beam 304 on beam-limit aperture array without forming a crossover, and in a second setting, may be configured to narrow primary electron beam 304 such that crossover 315 is formed downstream. In some embodiments, the number of windings or turns in the set of coils may determine whether the condenser lens may perform a coarse or a fine adjustment of beam focus. In some embodiments, condenser lens 310_2 may be configured to perform a fine adjustment of beam current of primary electron beam 304 after being adjusted by condenser lens 310_1.

In some embodiments, first condenser lens 310_1 may be configured to condense primary electron beam 304 and operable in a first mode and a second mode. In the first mode, condenser lens 310_1 may condense primary electron beam 304 without narrowing the beam or forming a crossover and primary electron beam 304 may have a first beam current. In the second mode, however, condenser lens 3101 may condense primary electron beam 304 sufficiently such that it forms a crossover (e.g., crossover 315) and primary electron beam 304 may have a second beam current. The second beam current may be higher than the first beam current. In some embodiments, condenser lens 3102 may be configured to fine tune first beam current in the first mode and fine tune second beam current in the second mode. Adjusting the second beam current in the second mode where a beam crossover is formed may include adjusting a location of the crossover along primary optical axis 301.

In some embodiments, a controller (e.g., controller 50) may be configured to independently control the current through condenser lens 310_1 and condenser lens 310_2. In the coplanar configuration of condenser lenses 310_1 and 310_2, controller 50 may be configured to independently supply and adjust electrical current through the first and second set of coils based on the mode in which condenser lens 310_1 is operating, or based on the operation mode of the apparatus. This may be useful in applications where it is desirable to not just form a crossover but also be able to adjust a location of beam crossover along primary optical axis 301.

In some cases, slight variations in position of beam-limit aperture array 335 due to mechanical drift or vibrations, for example, may negatively impact the achievable resolution or probe current. For example, if the geometric center of aperture 337 of beam-limit aperture array is misaligned with primary optical axis 301, either the probe current of primary electron beam 304 passing through may be lower than desired, or the off-axis aberrations may be higher than expected, or both. One of the ways to mitigate the impact of misalignment of beam-limit aperture array 335 may include adjusting the second beam current of condenser lens 310_2 to adjust location of crossover 315 such that primary electron beam 304 crosses over while passing through aperture 337 of beam-limit aperture array 335. In such a case, the location of beam crossover 315 may be coplanar with beam-limit aperture array 335.

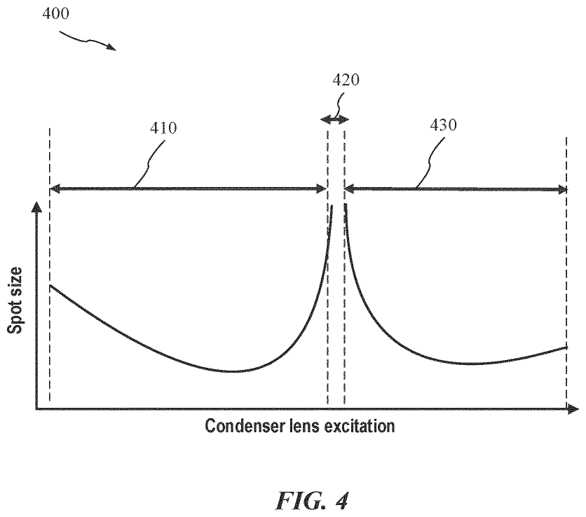

Reference is now made to FIG. 4, which illustrates a simulated plot 400 for a software assisted mode-switching in a single electron beam inspection tool, consistent with embodiments of the present disclosure. A controller (e.g., controller 50 of FIG. 2) may comprise a processor configured to execute instructions and a software-implemented algorithm for software assisted mode-switching. Simulated plot 400 represents a relationship between the achievable resolution (shown in y-axis) and the condenser lens (e.g., condenser lens 310 of apparatus 300B or 300C) excitation or probe current. The spot size (nanometers, nm), as used herein, represents a size of the probe spot formed by primary electron beam 304 on a sample. A smaller probe spot corresponds to a higher resolution achievable by the probing beam. For example, to resolve two parallel lines separated by a horizontal distance of 40 nm, a probe spot size of 40 nm or lower may be desirable.

As illustrated in FIG. 4, simulated plot 400 may comprise a low probe current region 410, a focus-less region 420, and a high probe current region 430, for a given aperture size of beam-limit aperture array (e.g., beam-limit aperture array 335 of FIG. 3C). In low probe current region 410, also referred to as normal mode or non-crossover mode region, the spot size of primary electron beam 304 may initially decrease as the condenser lens excitation is increased. However, as the condenser lens excitation increases further beyond a threshold value, the spot size increases owing to increased Gaussian image size and Coulomb interaction between electrons, among other things. If the probe current is increased by using a larger aperture of beam-limit aperture array 335, the spot size may increase due to spherical and chromatic aberrations of off-axis electrons, for example. Therefore, in the non-crossover mode, the range of condenser lens excitations resulting in small spot size, and resultantly high resolution, may be limited.

In high probe current region 430, also referred to as crossover mode region, increasing the condenser lens excitation may decrease spot size due to the reduction of Gaussian image size before the aberration contribution and Coulomb interaction contribution increase, thereby increasing the imaging resolution. The crossover mode of imaging may have numerous advantages over the existing non-crossover mode of imaging in voltage contrast inspection, among other things. A crossover mode of imaging may have some or all of the advantages discussed herein:

1. Large Probe Current—The ability to switch between a non-crossover mode and a crossover mode of operation allows the inspection system to inspect samples with a large probe current at small half-angles. For example, in the non-crossover mode, while the probe currents may be large, the beam half-angles are also large, which may introduce spherical and chromatic aberrations that can negatively impact the spot size. On the other hand, in crossover mode, the beam half-angles may be limited by controlling the excitation of the condenser lens. Therefore, by switching between modes of operation, large probe currents and small half-angles may be obtained.
2. High Imaging Resolution—Conventional inspection systems may include multiple beam crossovers before the primary electron beam is incident on the sample surface. In the proposed crossover mode of operation, the primary electron beam may only have one location of beam crossover (e.g., crossover 315 of FIG. 3B), which may reduce Coulombic interactions between electrons, thereby achieving high imaging resolution. For example, the beam crosses over only at one location between beam-limit aperture array 335 and objective lens 332.
3. High Imaging Stability—The voltage contrast images obtained after multiple scans of regions of interest at high probe current show excellent stability without undesirable charging or loss of signal.
4. Improved Inspection Throughput—For an optimum resolution, the beam current density in crossover mode is significantly higher compared to the non-crossover mode of operation. The high probe current may reduce the number of scans required to achieve the desired contrast levels to inspect defects, thereby improving inspection throughput while maintaining high resolution and stability.
5. Upgradability—The proposed mode of operation may be performed without changes to system hardware, allowing the existing tools to easily incorporate the capability of crossover mode of operation.
6. Mode-switchability—The operation mode of the inspection tool may be switched from non-crossover mode to crossover mode based on guidance from simulation data. The simulation data may be generated using a software algorithm based on recipes and current tables including data associated with condenser lens excitation and the corresponding probe currents for a given aperture size.

The software-implemented algorithm to achieve mode-switching on an inspection tool may include correlating the probe current of primary electron beam 304 with condenser lens excitation settings. In some embodiments, a processor, a microprocessor, or a computer may provide the hardware to execute the software-implemented algorithm or instructions therein. In some embodiments, controller 50 may be configured to execute the software-implemented algorithm or instructions to perform mode-switching, for example, based on information associated with probe current and condenser lens settings. In some embodiments, controller 50 may include the processor or the microprocessor configured to execute the software-implemented algorithm to perform software assisted mode-switching. In some embodiments, correlating the probe current with condenser lens excitation or condenser lens current, in case of electromagnetic lenses, may include generating a table of probe current and corresponding condenser lens current values. Such tables may be referred to as “current tables.” In some embodiments, a first current table may be generated for a non-crossover mode of operation and a second current table may be generated for a crossover mode of operation. In some embodiments, one or more recipes may be created, wherein each recipe comprises one or more current tables. The data in current tables may be referred to or accessed to determine the achievable resolution for a given excitation signal applied to condenser lens, or probe current of primary electron beam 304 for a given excitation signal applied to condenser lens, among other things.

In some embodiments, the software algorithm may be configured to enable switching the operation of the inspection apparatus from a non-crossover mode to a crossover mode, or a crossover mode to a non-crossover mode based on the desired probe current or desired resolution. For example, if a resolution of 40 nm is desirable at a probe current of 200 nA, the software may implement a mode-switch from normal mode to crossover mode, based on the information stored in the current tables associating a condenser lens current value to an achievable probe current. The software may also take into account the aperture size, the landing energy, the electron source intensity, among other things.

Referring to FIG. 4, simulated plot 400 represents a relationship between condenser lens excitation or probe current and spot size or resolution, as simulated using a software algorithm. In some embodiments, information associated with current tables may be stored in a database, or a storage system, a memory space, a local memory module, or on a remote network. The information stored in current tables may be accessed by the software application or a processor configured to execute instructions to access the current tables.

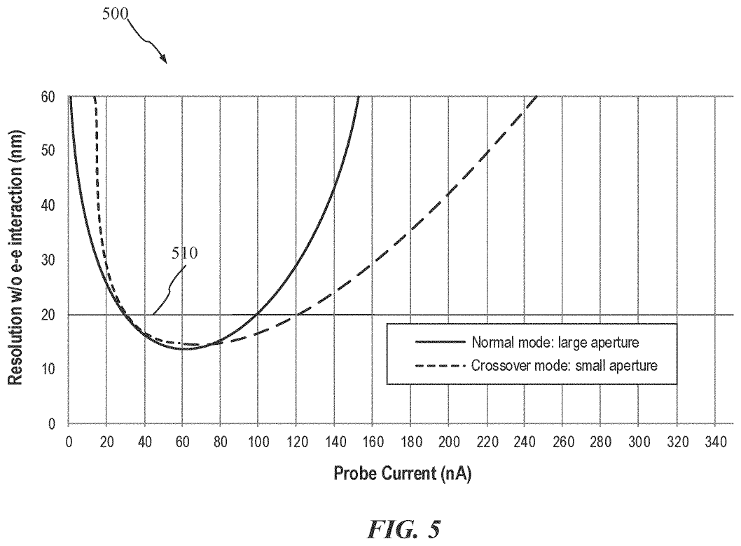

Reference is now made to FIG. 5, which illustrates a simulated plot 500 representing a relationship between resolution (without electron-electron interaction) and probe current (nanoAmperes) of primary electron beam 304 under a normal mode or operation (solid curve) and a crossover mode of operation (dashed curve), consistent with embodiments of the present disclosure.

In simulated plot 500, the solid curve represents the achievable resolution in normal mode for a range of probe current of primary electron beam 304 passing through a large beam-limit aperture. For illustrative purposes only, reference line 510 indicates a reference peak resolution of 20 nm or less. As shown, in the normal mode, based on simulated values from the algorithm, the reference peak resolution of 20 nm or less may be achieved over a probe current range of 30-100 nA. On the other hand, in the crossover mode, the reference peak resolution of 20 nm or less may be achieved over a broader probe current range of 30-120 nA, with a smaller beam-limit aperture. As a comparison, for probe current higher than 80 nA, the crossover mode has better resolution than the normal mode based on existing aperture selection in the system. In theory, the resolution in the normal non-crossover mode may be improved, and in some cases may be even higher than the crossover mode, by selecting a larger aperture, if available in the inspection apparatus. But if the aperture size selection is limited, crossover mode may generate images with better resolution than corresponding normal mode images. Further, because high probe current may be achieved with smaller beam-limit aperture sizes, the half-angles may be small, which may help reduce the off-axis aberrations such as spherical and chromatic aberrations.

In some embodiments, the information from simulations may be stored in information database such as, but not limited to, a network, a local memory space, a remote memory space, a database, a server, among other storage media. In some embodiments, reference tables or current tables may be generated using the simulated information. For example, the software may tabulate the probe current values and the corresponding achievable resolution for a given mode of operation. The simulated information database may further include aperture size, condenser lens excitation currents, excitation voltages, and other tool characteristics. In some embodiments, a user may use the reference tables or current tables and the simulated data as a guidance for operation of the inspection tool to achieve desirable results.

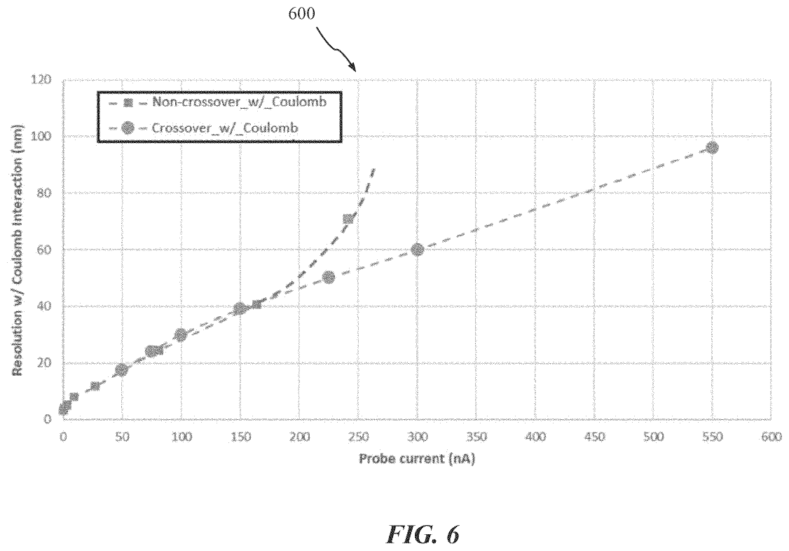

Reference is now made to FIG. 6, which illustrates a simulated plot 600 representing a relationship between achievable resolution and corresponding probe currents, consistent with embodiments of the present disclosure. Plot 600 further illustrates a comparison of the resolution and probe current curves for the inspection tool operating in a normal non-crossover mode and crossover mode. In plot 600, the curve with solid squares represents the relationship between achievable resolution and corresponding probe current under normal mode of operation, and the curve with solid circles represents the relationship between achievable resolution and corresponding probe current under crossover mode of operation, for aperture sizes over a broad range.

Under normal mode of operation, one of several ways to improve imaging resolution may include appropriately selecting the beam-limit aperture size. In some embodiments, the software may generate reference tables or look-up tables including information associated with resolution, probe current, condenser lens current, aperture size, objective lens characteristics, electron source emission characteristics, among other factors, to provide guidance to a user for operation conditions. In some embodiments, the software may allow a user to generate and customize reference tables based on the simulated data. In some embodiments, the crossover mode of operation may be desirable because the imaging resolution can be maintained over a large probe current range for a given aperture size. As an example, under normal mode of operation, if the inspection tool allows for larger apertures or a broader range of aperture sizes at current larger than 200 nA, the non-crossover mode may have similar or better resolution than the non-crossover mode. In the crossover mode, however, at large probe currents, the imaging resolution may be higher because it may use a smaller aperture among the existing available apertures. As described previously, the crossover mode of operation may further allow the user to increase the probe current range and the probe current values by selecting larger apertures in comparison to normal mode of operation. This may be desirable because a large probe current may allow a user to reduce the number of scans required to obtain a high contrast image for voltage contrast inspection techniques, resulting in improved throughput and efficiency of inspection.

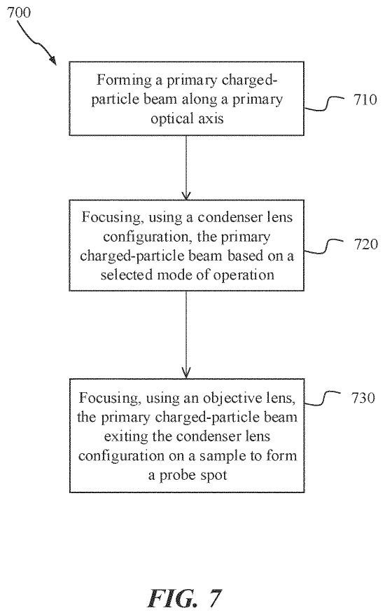

Reference is now made to FIG. 7, which illustrates a process flowchart representing an exemplary method 700 of inspecting a sample using a single-beam inspection apparatus, consistent with embodiments of the present disclosure. Method 700 may be performed by controller 50 of EBI system 100, as shown in FIG. 1, for example. Controller 50 may be programmed to implement one or more steps of method 700. For example, controller 50 may instruct a module of a charged particle beam apparatus to activate a charged-particle source to generate charged particle beam (e.g., electron beam), to adjust the excitation of one or more condenser lenses to adjust the position of the beam crossover, to perform mode-switching based on software-implemented algorithm, and carry out other functions.

In step 710, a charged-particle source or an electron source (e.g., cathode 303 of FIG. 3A) may be activated to emit charged particles, which upon passing through an aperture plate may form a charged-particle beam (e.g., primary electron beam 304 of FIG. 3A). The electron source may be activated by a controller (e.g., controller 50 of FIG. 1). For example, the electron source may be controlled to emit primary electrons to form an electron beam along a primary optical axis (e.g., primary optical axis 301 of FIG. 3A). The electron source may be activated remotely, for example, by using a software, an application, or a set of instructions for a processor of a controller to power the electron source through a control circuitry.

In step 720, the primary electron beam may be condensed using a condenser lens (e.g., condenser lens 310 of FIG. 3A or 3B) located downstream from the electron source and configured to receive the primary electron beam. The condenser lens may be configured to condense the primary electron beam based on a selected mode of operation. In some embodiments, the operation mode may be selected or switched manually by a user, however, in some embodiments, the operation mode may be selected or switched remotely through a software-implemented algorithm, based on simulated data. The two modes of operation include a non-crossover mode and a crossover mode.

In the non-crossover mode of operation, the condenser lens may be configured to condense the primary electron beam such that after exiting the condenser lens, primary electron beam is substantially parallel to the primary optical axis. The primary electron beam may be incident substantially perpendicular on a beam-limit aperture array (e.g., beam-limit aperture array 335 of FIG. 3A) and may pass through an aperture (e.g., aperture 337 of FIG. 3A). An objective lens (e.g., objective lens 332 of FIG. 3A) may receive the primary electron beam exiting the beam-limit aperture array and focus the primary beam on a sample surface to form a probe spot.

In the crossover mode of operation, the condenser lens may condense the primary electron beam sufficiently such that the beam forms a crossover (e.g., beam crossover 315 of FIG. 3A) along the primary optical axis on a crossover plane (e.g., crossover plane 340 of FIG. 3B). In some embodiments, beam crossover may be formed between the condenser lens and the objective lens. In some embodiments, the beam crossover may be formed between beam-limit aperture array and the objective lens. The location of beam crossover may be adjusted along primary optical axis based on an electrical excitation of condenser lens.

In step 730, objective lens may focus the primary electron beam exiting the condenser lens on the sample to form a probe spot. The probe current may be determined based on the aperture of the beam-limit aperture array through which the primary electron beam passes. In the crossover mode of operation, the primary electron beam may form a crossover before it is incident on the objective lens. The objective lens may be configured to focus the diverging beam, after crossover, on the sample surface.

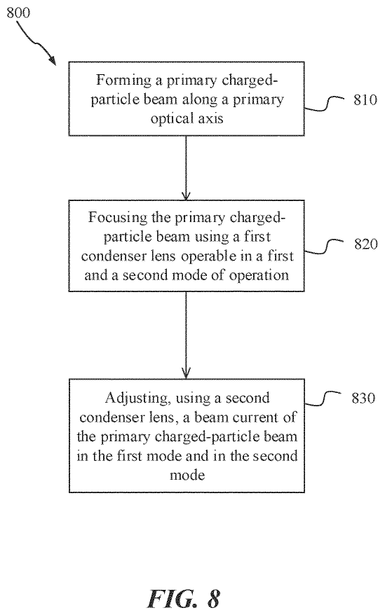

Reference is now made to FIG. 8, which illustrates a process flowchart representing an exemplary method 700 of inspecting a sample using a single-beam inspection apparatus, consistent with embodiments of the present disclosure. Method 800 may be performed by controller 50 of EBI system 100, as shown in FIG. 1, for example. Controller 50 may be programmed to implement one or more steps of method 800. For example, controller 50 may instruct a module of a charged particle beam apparatus to activate a charged-particle source to generate charged particle beam (e.g., electron beam), to adjust the excitation of one or more condenser lenses to adjust the position of the beam crossover, to perform mode-switching based on software-implemented algorithm and carry out other functions.

In step 810, a charged-particle source or an electron source (e.g., cathode 303 of FIG. 3A) may be activated to emit charged particles, which upon passing through an aperture plate may form a charged-particle beam (e.g., primary electron beam 304 of FIG. 3A). The electron source may be activated by a controller (e.g., controller 50 of FIG. 1). For example, the electron source may be controlled to emit primary electrons to form an electron beam along a primary optical axis (e.g., primary optical axis 301 of FIG. 3A). The electron source may be activated remotely, for example, by using a software, an application, or a set of instructions for a processor of a controller to power the electron source through a control circuitry.

In step 820, the primary electron beam may be condensed using a first condenser lens (e.g., first condenser lens 310_1 of FIG. 3C). The first condenser lens may be operable in a first and a second mode of operation. In the first mode, the first condenser lens may condense the primary electron beam such that it is incident perpendicularly on a beam-limit aperture array (e.g., beam-limit aperture array 335 of FIG. 3C). In the second mode of operation of the first condenser lens, the primary electron beam may be condensed sufficiently such that a beam crossover (e.g., crossover 315 of FIG. 3C) may be formed along the primary optical axis.

In step 830, a second condenser lens (e.g., second condenser lens 310_2 of FIG. 3C), located downstream from the first condenser lens, may adjust a first beam current of the primary electron beam in the first mode and adjust a second beam current of the primary electron beam in the second mode. The second beam current may be larger than the first beam current because the crossover point is between the beam-limit aperture array and the objective lens. In some embodiments, if the crossover point is above the beam-limit aperture, then the first beam current may be larger than the second beam current. In some embodiments, the first and the second condenser lens may comprise an electromagnetic lens. In some embodiments, the first condenser lens may comprise a first set of coils through which an electrical current may be passed. Adjusting the electrical current passing through the first set of coils may cause the operation of the first condenser lens to switch from the first mode to the second mode, or a non-crossover mode to a crossover mode. The second condenser lens may comprise a second set of coils through which an electrical current may be passed. Adjusting the electrical current through the second set of coils may allow an adjustment of beam current of the primary electron beam. The electrical current through the first set of coils and through the second set of coils may be independently controlled and adjusted. In some embodiments, adjusting the electrical current passing through the second set of coils may adjust a location of the crossover formed along the primary optical axis.

An objective lens may focus the primary electron beam exiting the second condenser lens on the sample to form a probe spot. The probe current may be determined based on an aperture (e.g., aperture 337 of FIG. 3C) of the beam-limit aperture array through which the primary electron beam passes. In the crossover mode of operation, the primary electron beam may form a crossover before it is incident on the objective lens. The objective lens may be configured to focus the diverging beam, after crossover, on the sample surface.

A non-transitory computer readable medium may be provided that stores instructions for a processor of a controller (e.g., controller 50 of FIG. 1) to carry out image inspection, image acquisition, activating charged-particle source, adjusting the electrical excitation of one or more condenser lens, focusing the primary electron beam using one or more condenser lens, focusing the primary electron beam on the sample using objective lens, switching between modes of operation by adjusting the condenser lens current or voltage signal, executing instructions in a software-implemented algorithm to switch operation modes of the first condenser lens, moving the sample stage to adjust the position of the sample, etc. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments of the present disclosure may further be described using the following clauses:

1. A charged-particle beam apparatus comprising:
a charged-particle source configured to emit charged particles;
an aperture plate configured to form a primary charged-particle beam along a primary optical axis;
a condenser lens configuration configured to condense the primary charged-particle beam based on a selected mode of operation of the apparatus, wherein the selected mode of operation comprises a first mode and a second mode, and wherein:
in the first mode of operation, the condenser lens configuration is configured to condense the primary charged-particle beam, and
in the second mode of operation, the condenser lens configuration is configured to condense the primary charged-particle beam sufficiently to form a crossover between the condenser lens configuration and an objective lens of the apparatus.
   2. The apparatus of clause 1, wherein the objective lens is located downstream from the condenser lens configuration and configured to focus the primary charged-particle beam exiting the condenser lens configuration on a surface of a sample to form a probe spot.
   3. The apparatus of any one of clauses 1 and 2, further comprising a beam-limit aperture array located between the condenser lens configuration and the objective lens along the primary optical axis, wherein the crossover is formed between the beam-limit aperture array and the objective lens.
   4. The apparatus of any one of clauses 1-3, further comprising a pre-beam limit aperture array located upstream from the condenser lens configuration.
   5. The apparatus of any one of clauses 3 and 4, wherein the crossover is formed coplanar with the beam-limit aperture array.
   6. The apparatus of any one of clauses 1-5, further comprising a controller having circuitry configured to switch the operation of the apparatus from the first mode to the second mode.
   7. The apparatus of clause 6, wherein the controller includes circuitry to adjust a first excitation of the condenser lens configuration to cause the apparatus to switch from the first mode to the second mode.
   8. The apparatus of any one of clauses 3-7, wherein in the first mode of operation, a first probe current of the primary charged-particle beam is determined based on a size of an aperture of the beam-limit aperture array through which the primary charged-particle beam passes.
   9. The apparatus of clause 8, wherein in the second mode of operation, a second probe current of the primary charged-particle beam passing through the aperture is determined based on a second excitation of the condenser lens configuration, and wherein the second probe current is larger than the first probe current.
   10. The apparatus of clause 9, wherein in the second mode of operation, an adjustment of the second excitation of the condenser lens configuration adjusts a location of the crossover plane along the primary optical axis with respect to the objective lens.
   11. The apparatus of any one of clauses 1-10, wherein the condenser lens configuration comprises an electromagnetic lens.
   12. The apparatus of any one of clauses 1-11, wherein the first mode comprises a non-crossover mode of operation and the second mode comprises a crossover mode of operation.
   13. The apparatus of any one of clauses 1-12, wherein the condenser lens configuration comprises: a first condenser lens comprising a first set of coils; and a second condenser lens comprising a second set of coils, wherein an electrical current through each of the first and the second set of coils is independently adjustable.
   14. The apparatus of clause 13, wherein the second condenser lens is located downstream from the first condenser lens.
   15. The apparatus of clause 14, wherein the second condenser lens is coplanar with the first condenser lens.
   16. A method of inspecting a sample using a charged-particle beam apparatus, the method comprising:
forming a primary charged-particle beam along a primary optical axis from charged particles emitted by a charged-particle source;
condensing, using a condenser lens configuration, the primary charged-particle beam based on a selected mode of operation of the apparatus comprising a first mode and a second mode, wherein: operating in the first mode comprises condensing the primary charged-particle beam using the condenser lens configuration, and
operating in the second mode comprises condensing the primary charged-particle beam sufficiently to form a crossover between the condenser lens configuration and an objective lens of the apparatus; and focusing, using an objective lens, the primary charged-particle beam exiting the condenser lens configuration on a surface of the sample to form a probe spot.
   17. The method of clause 16, further comprising switching between the first and the second modes of operation by adjusting a first excitation of the condenser lens configuration.
   18. The method of any one of clauses 16 and 17, further comprising adjusting a location of the crossover plane along the primary optical axis with respect to the objective lens by adjusting a second excitation of the condenser lens configuration.
   19. The method of any one of clauses 16-18, further comprising determining, in the first mode, a first probe current of the primary charged-particle beam based on a size of an aperture of a beam-limit aperture array through which the primary charged-particle beam passes.
   20. The method of clause 19, further comprising determining, in the second mode, a second probe current of the primary charged-particle beam passing through the aperture based on a second excitation of the condenser lens configuration.
   21. The method of clause 20, wherein the second probe current is larger than the first probe current.
   22. The method of any one of clauses 16-21, wherein the condenser lens configuration comprises an electrostatic or an electromagnetic lens.
   23. The method of any one of clauses 16-22, wherein the first mode comprises a non-crossover mode and the second mode comprises a crossover mode of operation.
   24. A non-transitory computer readable medium storing a set of instructions that is executable by one or more processors of a charged-particle beam apparatus to cause the charged particle beam apparatus to perform a method comprising:
forming a primary charged-particle beam along a primary optical axis from charged particles emitted by a charged-particle source;
condensing, using a condenser lens configuration, the primary charged-particle beam based on a selected mode of operation comprising a first mode and a second mode of the apparatus, wherein: operating in the first mode comprises condensing the primary charged-particle beam using the condenser lens configuration, and
operating in the second mode comprises condensing the primary charged-particle beam to form a crossover between the condenser lens configuration and an objective lens of the apparatus; and focusing the primary charged-particle beam exiting the condenser lens configuration on a surface of the sample to form a probe spot.
   25. The non-transitory computer readable medium of clause 24, wherein the set of instructions that is executable by one or more processors of the charged-particle beam apparatus causes the charged-particle beam apparatus to further perform switching between the first and the second modes of operation by adjusting a first excitation of the condenser lens configuration.
   26. The non-transitory computer readable medium of any one of clauses 24 and 25, wherein the set of instructions that is executable by one or more processors of the charged-particle beam apparatus causes the charged-particle beam apparatus to further perform adjusting a location of the crossover plane along the primary optical axis with respect to the objective lens by adjusting a second excitation of the condenser lens configuration.
   27. The non-transitory computer readable medium of any one of clauses 24-26, wherein the set of instructions that is executable by one or more processors of the charged-particle beam apparatus causes the charged-particle beam apparatus to further perform determining, in the first mode, a first probe current of the primary charged-particle beam based on a size of an aperture of a beam-limit aperture array through which the primary charged-particle beam passes.
   28. The non-transitory computer readable medium of clause 27, wherein the set of instructions that is executable by one or more processors of the charged-particle beam apparatus causes the charged-particle beam apparatus to further perform determining, in the second mode, a second probe current of the primary charged-particle beam passing through the aperture based on a second excitation of the condenser lens configuration.
   29. A charged-particle beam apparatus comprising:
a charged-particle source configured to emit charged particles;
an aperture plate configured to form a primary charged-particle beam along a primary optical axis from the emitted charged particles;
a first condenser lens configured to condense the primary charged-particle beam and operable in a first mode and a second mode, wherein:
in the first mode, the first condenser lens is configured to condense the primary charged-particle beam, and
in the second mode, the first condenser lens is configured to condense the primary charged-particle beam sufficiently to form a crossover along the primary optical axis; and
a second condenser lens configured to adjust a first beam current of the primary charged-particle beam in the first mode and adjust a second beam current of the primary charged-particle beam in the second mode, wherein the second beam current is larger than the first beam current.
   30. The apparatus of clause 29, wherein the first and the second condenser lens constitute a condenser lens configuration, and wherein the second condenser lens is located downstream from the first condenser lens.
   31. The apparatus of any one of clauses 29 and 30, wherein the second condenser lens is coplanar with the first condenser lens.
   32. The apparatus of any one of clauses 29-31, wherein each of the first and the second condenser lens comprise an electromagnetic lens.
   33. The apparatus of any one of clauses 29-32, wherein the first condenser lens comprises a first set of coils and the second condenser lens comprises a second set of coils.
   34. The apparatus of clause 33, wherein an electrical current passing through each of the first and the second set of coils is independently adjustable.
   35. The apparatus of clause 34, wherein an adjustment of the electrical current passing through the first set of coils causes the first condenser lens to switch operation between the first and the second mode.
   36. The apparatus of any one of clauses 33-35, wherein an adjustment of the electrical current passing through the second set of coils causes an adjustment of the beam current of the primary charged-beam in the first mode and the second mode.
   37. The apparatus of clause 36, wherein the adjustment of the electrical current passing through the second set of coils causes an adjustment of a location of the crossover along the primary optical axis.
   38. The apparatus of any one of clauses 30-37, further comprising an objective lens configured to focus the primary charged-particle beam exiting the condenser lens configuration on a surface of a sample to form a probe spot.
   39. The apparatus of clause 38, further comprising a beam-limit aperture array located between the condenser lens configuration and the objective lens, wherein the crossover is formed between the beam-limit aperture array and the objective lens along the primary optical axis.
   40. The apparatus of any one of clauses 30-39, further comprising a pre-beam limit aperture array located upstream from the condenser lens configuration.
   41. The apparatus of any one of clauses 39 and 40, wherein the crossover is formed coplanar with the beam-limit aperture array.
   42. The aperture of any one of clauses 29-41, further comprising a controller having circuitry configured to switch an operation of the first condenser lens between the first and the second mode.
   43. The apparatus of any one of clauses 29-42, wherein the first mode comprises a non-crossover mode and the second mode comprises a crossover mode of operation of the apparatus.
   44. A method of inspecting a sample using a charged-particle beam apparatus, the method comprising:
forming a primary charged-particle beam along a primary optical axis from charged particles emitted by a charged-particle source;
condensing the primary charged-particle beam, using a first condenser lens operable in a first mode and
a second mode, wherein
in the first mode, the first condenser lens is configured to condense the primary charged-particle beam, and
in the second mode, the first condenser lens is configured to condense the primary charged-particle beam sufficiently to form a crossover along the primary optical axis; and adjusting, using a second condenser lens, a first beam current of the primary charged-particle beam in the first mode and a second beam current of the primary charged-particle beam in the second mode, wherein the second beam current is larger than the first beam current.
   45. The method of clause 44, wherein the first and the second condenser lens constitute a condenser lens configuration, and wherein the second condenser lens is located downstream from the first condenser lens.
   46. The method of clause 45, wherein the second condenser lens is coplanar with the first condenser lens.
   47. The method of any one of clauses 44-46, wherein each of the first and the second condenser lens comprise an electromagnetic lens.
   48. The method of any one of clauses 44-47, wherein the first condenser lens comprises a first set of coils and the second condenser lens comprises a second set of coils.
   49. The method of clause 48, further comprising independently adjusting an electrical current passing through each of the first and the second set of coils.
   50. The method of any one of clauses 48 and 49, further comprising switching operation of the first condenser lens between the first and the second mode by adjusting the electrical current passing through the first set of coils.
   51. The method of any one of clauses 48-50, further comprising adjusting the beam current of the primary charged-beam in the first mode and the second mode by adjusting the electrical current passing through the second set of coils.
   52. The method of any one of clauses 48-51, further comprising adjusting a location of the crossover along the primary optical axis by adjusting the electrical current passing through the second set of coils.
   53. The method of any one of clauses 44-52, further comprising focusing, using an objective lens, the primary charged-particle beam exiting the condenser lens configuration on a surface of a sample to form a probe spot.
   54. The method of any one of clauses 44-53, wherein a beam-limit aperture array is located between the condenser lens configuration and the objective lens, and wherein the crossover is formed between the beam-limit aperture array and the objective lens along the primary optical axis.
   55. The method of clause 54, wherein the crossover is formed coplanar with the beam-limit aperture array.
   56. The method of any one of clauses 44-55, wherein the first mode comprises a non-crossover mode and the second mode comprises a crossover mode of operation of the condenser lens.
   57. A non-transitory computer readable medium storing a set of instructions that is executable by one or more processors of a charged-particle beam apparatus to cause the charged particle beam apparatus to perform a method comprising:
forming a primary charged-particle beam along a primary optical axis from charged particles emitted by a charged-particle source;
condensing the primary charged-particle beam, using a first condenser lens operable in a first mode and
a second mode, wherein
in the first mode, the first condenser lens is configured to condense the primary charged-particle beam, and
in the second mode, the first condenser lens is configured to condense the primary charged-particle beam sufficiently to form a crossover along the primary optical axis; and
adjusting, using a second condenser lens, a first beam current of the primary charged-particle beam in the first mode and a second beam current of the primary charged-particle beam in the second mode, wherein the second beam current is larger than the first beam current.
   58. The non-transitory computer readable medium of clause 57, wherein the first and the second condenser lens of the charged-particle beam apparatus constitute a condenser lens configuration, and wherein the second condenser lens is located downstream from the first condenser lens.
   59. The non-transitory computer readable medium of clause 58, wherein the second condenser lens is coplanar with the first condenser lens.
   60. The non-transitory computer readable medium of any one of clauses 57-59, wherein each of the first and the second condenser lens comprise an electromagnetic lens.
   61. The non-transitory computer readable medium of any one of clauses 57-60, wherein the first condenser lens comprises a first set of coils and the second condenser lens comprises a second set of coils.
   62. The non-transitory computer readable medium of clause 61, wherein the set of instructions that is executable by one or more processors of the charged-particle beam apparatus causes the charged-particle beam apparatus to further perform independently adjusting an electrical current passing through each of the first and the second set of coils.
   63. The non-transitory computer readable medium of any one of clauses 61 and 62, wherein the set of instructions that is executable by one or more processors of the charged-particle beam apparatus causes the charged-particle beam apparatus to further perform a switching operation of the first condenser lens between the first and the second mode by adjusting the electrical current passing through the first set of coils.
   64. The non-transitory computer readable medium of any one of clauses 61-63, wherein the set of instructions that is executable by one or more processors of the charged-particle beam apparatus causes the charged-particle beam apparatus to further perform adjusting the beam current of the primary charged-beam in the first mode and the second mode by adjusting the electrical current passing through the second set of coils.
   65. The non-transitory computer readable medium of any one of clauses 61-64, wherein the set of instructions that is executable by one or more processors of the charged-particle beam apparatus causes the charged-particle beam apparatus to further perform adjusting a location of the crossover along the primary optical axis by adjusting the electrical current passing through the second set of coils.
   66. The non-transitory computer readable medium of any one of clauses 57-65, wherein the set of instructions that is executable by one or more processors of the charged-particle beam apparatus causes the charged-particle beam apparatus to further perform focusing, using an objective lens, the primary charged-particle beam exiting the condenser lens configuration on a surface of a sample to form a probe spot.
   67. The non-transitory computer readable medium of clause 66, wherein a beam-limit aperture array is located between the condenser lens configuration and the objective lens, and wherein the crossover is formed between the beam-limit aperture array and the objective lens along the primary optical axis.
   68. The non-transitory computer readable medium of clause 67, wherein the crossover is formed coplanar with the beam-limit aperture array.
   69. The non-transitory computer readable medium of any one of clauses 57-68, wherein the first mode comprises a non-crossover mode and the second mode comprises a crossover mode of operation of the condenser lens.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A charged-particle beam apparatus comprising:
a charged-particle source configured to emit charged particles;
an aperture plate configured to form a primary charged-particle beam along a primary optical axis;
a condenser lens configuration configured to condense the primary charged-particle beam based on a selected mode of operation of the apparatus, wherein the selected mode of operation comprises a first mode and a second mode, and wherein:
in the first mode of operation, the condenser lens configuration is configured to condense the primary charged-particle beam, and
in the second mode of operation, the condenser lens configuration is configured to condense the primary charged-particle beam sufficiently to form a crossover between the condenser lens configuration and an objective lens of the apparatus.

2. The apparatus of claim 1, wherein the objective lens is located downstream from the condenser lens configuration and configured to focus the primary charged-particle beam exiting the condenser lens configuration on a surface of a sample to form a probe spot.

3. The apparatus of claim 1, further comprising a beam-limit aperture array located between the condenser lens configuration and the objective lens along the primary optical axis, wherein the crossover is formed between the beam-limit aperture array and the objective lens.

4. The apparatus of claim 3, wherein the crossover is formed coplanar with the beam-limit aperture array.

5. The apparatus of claim 1, further comprising a controller having circuitry configured to switch the operation of the apparatus from the first mode to the second mode.

6. The apparatus of claim 5, wherein the controller includes circuitry to adjust a first excitation of the condenser lens configuration to cause the apparatus to switch from the first mode to the second mode.

7. The apparatus of claim 3, wherein in the first mode of operation, a first probe current of the primary charged-particle beam is determined based on a size of an aperture of the beam-limit aperture array through which the primary charged-particle beam passes.

8. The apparatus of claim 7, wherein in the second mode of operation, a second probe current of the primary charged-particle beam passing through the aperture is determined based on a second excitation of the condenser lens configuration, and wherein the second probe current is larger than the first probe current.

9. The apparatus of claim 8, wherein in the second mode of operation, an adjustment of the second excitation of the condenser lens configuration adjusts a location of a crossover plane along the primary optical axis with respect to the objective lens.

10. The apparatus of claim 1, wherein the condenser lens configuration comprises an electromagnetic lens.

11. The apparatus of claim 1, wherein the first mode comprises a non-crossover mode of operation and the second mode comprises a crossover mode of operation.

12. The apparatus of claim 1, wherein the condenser lens configuration comprises:
a first condenser lens comprising a first set of coils; and
a second condenser lens comprising a second set of coils, wherein an electrical current through each of the first and the second set of coils is independently adjustable.

13. The apparatus of claim 12, wherein the second condenser lens is located downstream from the first condenser lens.

14. The apparatus of claim 12, wherein the second condenser lens is coplanar with the first condenser lens.

15. A non-transitory computer readable medium storing a set of instructions that is executable by one or more processors of a charged-particle beam apparatus to cause the charged particle beam apparatus to perform a method comprising:
forming a primary charged-particle beam along a primary optical axis from charged particles emitted by a charged-particle source;
condensing, using a condenser lens configuration, the primary charged-particle beam based on a selected mode of operation comprising a first mode and a second mode of the apparatus, wherein:
operating in the first mode comprises condensing the primary charged-particle beam using the condenser lens configuration, and
operating in the second mode comprises condensing the primary charged-particle beam sufficiently to form a crossover between the condenser lens configuration and an objective lens of the apparatus; and
focusing the primary charged-particle beam exiting the condenser lens configuration on a surface of a sample to form a probe spot.

16. The non-transitory computer readable medium of claim 15, wherein the set of instructions that is executable by one or more processors of the charged-particle beam apparatus causes the charged-particle beam apparatus to further perform switching between the first and the second modes of operation by adjusting a first excitation of the condenser lens configuration.

17. The non-transitory computer readable medium of claim 15, wherein the set of instructions that is executable by one or more processors of the charged-particle beam apparatus causes the charged-particle beam apparatus to further perform adjusting a location of a crossover plane along the primary optical axis with respect to the objective lens by adjusting a second excitation of the condenser lens configuration.

18. The non-transitory computer readable medium of claim 15, wherein the set of instructions that is executable by one or more processors of the charged-particle beam apparatus causes the charged-particle beam apparatus to further perform determining, in the first mode, a first probe current of the primary charged-particle beam based on a size of an aperture of a beam-limit aperture array through which the primary charged-particle beam passes.

19. The non-transitory computer readable medium of claim 18, wherein the set of instructions that is executable by one or more processors of the charged-particle beam apparatus causes the charged-particle beam apparatus to further perform determining, in the second mode, a second probe current of the primary charged-particle beam passing through the aperture based on a second excitation of the condenser lens configuration.

20. A charged-particle beam apparatus comprising:
a charged-particle source configured to emit charged particles;
an aperture plate configured to form a primary charged-particle beam along a primary optical axis from the emitted charged particles;
a first condenser lens configured to condense the primary charged-particle beam and operable in a first mode and a second mode, wherein:
in the first mode, the first condenser lens is configured to condense the primary charged-particle beam, and
in the second mode, the first condenser lens is configured to condense the primary charged-particle beam sufficiently to form a crossover along the primary optical axis; and
a second condenser lens configured to adjust a first beam current of the primary charged-particle beam in the first mode and adjust a second beam current of the primary charged-particle beam in the second mode, wherein the second beam current is larger than the first beam current.
